(19) United States
(12) Patent Application Publication
(10) Pub. No.: US 2020/0098980 A1
(43) Pub. Date: Mar. 26, 2020

(54) METHOD FOR FORMING HIGH DENSITY STRUCTURES WITH IMPROVED RESIST ADHESION TO HARD MASK

(71) Applicant: Spin Memory, Inc., Fremont, CA (US)

(72) Inventors: Elizabeth A. Dobisz, San Jose, CA (US); Thomas D. Boone, San Carlos, CA (US); Yuan-Tung Chin, Fremont, CA (US)

(21) Appl. No.: 16/140,455

(22) Filed: Sep. 24, 2018

(51) Int. Cl. H01L 43/12; H01L 27/22; G11C 11/16

(52) U.S. Cl. CPC H01L 43/12; H01L 21/3086; G11C 11/161; H01L 27/222

(57) ABSTRACT

A method for manufacturing an array of small pitch small feature size structures on a wafer. The method includes depositing a device layer, depositing a hard mask layer over the device layer, depositing a thin SiO₂ adhesion layer over the hard mask layer and then forming a photoresist mask over the SiO₂ adhesion layer. The presence of the SiO₂ adhesion layer prevents toppling or deformation of the photoresist mask, thereby allowing the image of the photoresist mask to be accurately and reliably transferred onto the underlying hard mask. Then, the image of the hard mask can be accurately transferred to the underlying device layer.

### FIELD OF THE INVENTION

The present invention relates to magnetic random access memory (MRAM), magnetic logic, and magnetic neuromorphic computing devices, and more particularly to a method for forming small, high density structures with the use of a novel adhesion layer for improved resist mask formation.

### BACKGROUND

Magnetic Random Access Memory (MRAM) is a non-volatile data memory technology that stores data using magnetoresistive cells such as Magnetoresistive Tunnel Junction (MTJ) cells. At their most basic level, such MTJ elements include first and second magnetic layers that are separated by a thin, non-magnetic layer such as a tunnel barrier layer, which can be constructed of a material such as Mg—O. The first magnetic layer, which can be referred to as a reference layer, has a magnetization that is fixed in a direction that is perpendicular to that plane of the layer. The second magnetic layer, which can be referred to as a magnetic free layer, has a magnetization that is free to move so that it can be oriented in either of two directions that are both generally perpendicular to the plane of the magnetic free layer. Therefore, the magnetization of the free layer can be either parallel with the magnetization of the reference layer or anti-parallel with the direction of the reference layer (i.e. opposite to the direction of the reference layer).

The electrical resistance through the MTJ element in a direction perpendicular to the planes of the layers changes with the relative orientations of the magnetizations of the magnetic reference layer and magnetic free layer. When the magnetization of the magnetic free layer is oriented in the same direction as the magnetization of the magnetic reference layer, the electrical resistance through the MTJ element is at its lowest electrical resistance state. Conversely, when the magnetization of the magnetic free layer is in a direction that is opposite to that of the magnetic reference layer, the electrical resistance across the MTJ element is at its highest electrical resistance state.

The switching of the MTJ element between high and low resistance states results from electron spin transfer. An electron has a spin orientation. Generally, electrons flowing through a conductive material have random spin orientations with no net spin orientation. However, when electrons flow through a magnetized layer, the spin orientations of the electrons become aligned so that there is a net aligned orientation of electrons flowing through the magnetic layer, and the orientation of this alignment is dependent on the orientation of the magnetization of the magnetic layer through which they travel. When the orientations of the magnetizations of the free and reference layer are oriented in the same direction, the majority spin of the electrons in the free layer are is in the same direction as the orientation of the majority spin of the electrons in the reference layer. Because these electron spins are in generally the same direction, the electrons can pass relatively easily through the tunnel barrier layer. However, if the orientations of the magnetizations of the free and reference layers are opposite to one another, the spin of majority electrons in the free layer will be generally opposite to the majority spin of electrons in the reference layer. In this case, electrons cannot easily pass through the barrier layer, resulting in a higher electrical resistance through the MTJ stack.

Because the MTJ element can be switched between low and high electrical resistance states, it can be used as a memory element to store a bit of data. For example, the low resistance state can be read as an on or “1”, whereas the high resistance state can be read as a “0”. In addition, because the magnetic orientation of the magnetic free layer remains in its switched orientation without any electrical power to the element, it provides a robust, non-volatile data memory bit.

To write a bit of data to the MTJ cell, the magnetic orientation of the magnetic free layer can be switched from a first direction to a second direction that is 180 degrees from the first direction. This can be accomplished, for example, by applying a current through the MTJ element in a direction that is perpendicular to the planes of the layers of the MTJ element. An electrical current applied in one direction will switch the magnetization of the free layer to a first orientation, whereas switching the direction of the current and such that it is applied in a second direction will switch the magnetization of the free layer to a second, opposite orientation. Once the magnetization of the free layer has been switched by the current, the state of the MTJ element can be read by reading a voltage across the MTJ element, thereby determining whether the MTJ element is in a “1” or “0” bit state. Advantageously, once the switching electrical current has been removed, the magnetic state of the free layer will remain in the switched orientation until such time as another electrical current is applied to again switch the MTJ element. Therefore, the recorded date bit is non-volatile in that it remains intact in the absence of any electrical power.

In order to increase data density in a magnetic random access structure it is necessary to form very small pillar structures in a very high density array. However, certain manufacturing challenge can inhibit the ability to produce such high density structures in a reliable manner. For example, very high density photoresist mask structure are prone to deformation, such as the toppling of mask features after exposure and development and prior to image transfer to an underlying hard mask. Therefore, there remains a need for a process for reliably forming very small, high density, high quality arrays of features.

### SUMMARY

The present invention provides a method for forming a high-density array of features. The method includes forming a device material layer on a wafer and depositing a hard mask layer over the device material layer. A SiO₂ adhesion layer is then deposited over the hard mask layer and a photoresist mask is formed over the SiO₂ adhesion layer. The image of the photoresist mask is transferred onto the underlying SiO₂ adhesion layer and hard mask layer, and then the image of the hard mask layer is transferred onto the underlying device material layer to form an array of device features.

The SiO₂ adhesion layer is preferably very thin, preferably no thicker than 1 nm in order to minimize the increase in thickness of the material removed by the first image transfer process. After depositing the SiO₂ adhesion layer, a baking process can be performed to remove water from the SiO₂ adhesion layer. This baking step can be beneficial, because SiO₂ is very hydroscopic. After baking, the SiO₂ adhesion layer can be treated with an adhesion promoter such as hexamethyldisilazane (HMDS).

Photoresist masks for patterning very high-density structures need to have very small feature widths. However, the photoresist mask features also need to have a sufficiently large thickness in the height direction to withstand the image transfer process (e.g. reactive ion etching). This means that the photoresist features configured to define a high-density array will have a high aspect ratio, of at least 2.5/1. In addition, the mechanical stability of the mask pillars is further stressed by surface tension forces in the developer solution, which tend to pull the mask pillars toward one another. The presence of the SiO₂ adhesion layer advantageously prevents toppling or other deformation of the photoresist mask, thereby allowing the image of the photoresist mask to be accurately and reliably transferred to the underlying hard mask and device layer.

These and other features and advantages of the invention will be apparent upon reading of the following detailed description of the embodiments taken in conjunction with the figures in which like reference numeral indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic, cross sectional view of a perpendicular magnetic tunnel junction (pMTJ) element, such as might be used in an embodiment of the invention;

FIG. 2 is a top-down view of an array of pillar structures;

FIG. 3-7 are side cross-sectional views of a wafer in various intermediate stages of manufacture, illustrating a method for forming an array of structures on a wafer;

and

FIG. 8 is a flowchart illustrating a process for forming structures on a wafer.

### DETAILED DESCRIPTION

The following description is of the best embodiments presently contemplated for carrying out this invention. This description is made for the purpose of illustrating the general principles of this invention and is not meant to limit the inventive concepts claimed herein.

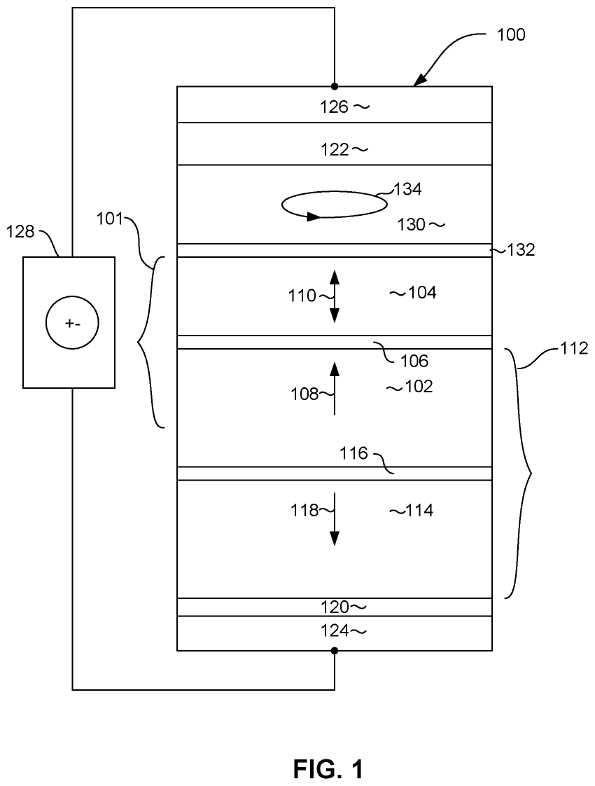

Referring now to FIG. 1, a magnetic memory element 100 can be in the form a of a perpendicular magnetic tunnel junction (pMTJ) memory element. The magnetic memory element can include an MTJ 101 that can include a magnetic reference layer 102, a magnetic free layer 104 and a thin, non-magnetic, electrically insulating magnetic barrier layer 106 located between the magnetic reference layer 102, and magnetic free layer 104. The barrier layer 106 can be an oxide such as MgO. The magnetic reference layer has a magnetization 108 that is fixed in a direction that is preferably perpendicular to the plane of the layers as indicated by arrow 108. The magnetic free layer has a magnetization 110 that can be in either of two directions perpendicular to the plane of the layer 104. While the magnetization 110 of the free layer remains in either of two directions perpendicular to the plane of the layer 104 in a quiescent state, it can be moved between these two directions as will be described in greater detail herein below. When the magnetization 110 of the magnetic free layer 104 is in the same direction as the magnetization 108 of the reference layer 102, the electrical resistance across the layers 102, 106, 104 is at a low resistance state. Conversely, when the magnetization 110 of the free layer 104 is opposite to the magnetization 108 of the reference layer 102, the electrical resistance across the layers 102, 106, 104 is in a high resistance state.

The magnetic reference layer 102 can be part of an anti-parallel magnetic pinning structure 112 that can include a magnetic keeper layer 114, and a non-magnetic, antiparallel coupling layer 116 located between the keeper layer 114 and reference layer 102. The antiparallel coupling layer 116 can be a material such as Ru and can be constructed to have a thickness such that it will ferromagnetically antiparallel couple the layers 114, 102. The antiparallel coupling between the layers 114, 102 pins the magnetization 108 of the reference layer 102 in a direction opposite to the direction of magnetization 118 of the keeper layer 114.

A seed layer 120 may be provided near the bottom of the memory element 100 to initiate a desired crystalline structure in the above deposited layers. A capping layer 122 may be provided near the top of the memory element 100 to protect the underlying layers during manufacture, such as during high temperature annealing and from exposure to ambient atmosphere. Also, electrodes 124, 126 may be provided at the top and bottom of the memory element 100. The electrodes 124, 126 may be constructed of a non-magnetic, electrically conductive material such as Ta, W, Cu and Al can provide electrical connection with circuitry 128 that can include a current source and can further include circuitry for reading an electrical resistance across the memory element 100.

The magnetic free layer 104 has a perpendicular magnetic anisotropy that causes the magnetization 110 of the free layer 104 to remain stable in one of two directions perpendicular to the plane of the free layer 104. In a write mode, the orientation of the magnetization 110 of the free layer 104 can be switched between these two directions by applying an electrical current through the memory element 100 from the circuitry 128. A current in one direction will cause the memory element to flip to a first orientation, and a current in an opposite direction will cause the magnetization to flip to a second, opposite direction. For example, if the magnetization 110 is initially oriented in a downward direction in FIG. 1, applying a current in a downward direction through the element 100 will cause electrons to flow in an opposite direction upward through the element 100. The electrons travelling through the reference layer will become spin polarized as a result of the magnetization 108 of the reference layer 102. These spin polarized electrons cause a spin torque on the magnetization 110 of the free layer 104, which causes the magnetization to flip directions.

On the other hand, if the magnetization 110 of the free layer 104 is initially in an upward direction in FIG. 1, applying an electrical current through the element 100 in an upward direction will cause electrons to flow in an opposite direction, downward through the element 100. However, because the magnetization 110 of the free layer 104 is opposite to the magnetization 108 of the reference layer 102, the electrons with an opposite spin will not be able to pass through the barrier layer 106 to the reference layer 102. As a result, the electrons having an opposite spin will accumulate at the junction between the free layer 104 and barrier layer 106. This accumulation of spin polarized electrons causes a spin torque that causes the magnetization 110 of the free layer 104 to flip from a downward direction to an upward direction.

In order to assist the switching of the magnetization 110 of the free layer 104, the memory element 100 may include a spin polarization layer 130 formed above the free layer 104. The spin polarization layer can be separated from the free layer 104 by a coupling layer 132. The spin polarization layer 130 has a magnetic anisotropy that causes it to have a magnetization 134 with a primary component oriented in the in-plane direction (e.g. perpendicular to the magnetizations 110, 108 of the free and reference layers 104, 102. The magnetization 134, of the spin polarization layer 130 may either be fixed or can move in a precessional manner as shown in FIG. 100. The magnetization 134 of the spin polarization layer 130 causes a spin torque on the free layer 104 that assists in moving its magnetization away from its quiescent state perpendicular to the plane of the free layer 104. This allows the magnetization 110 of the free layer 104 to more easily flip using less energy when applying a write current to the memory element 100.

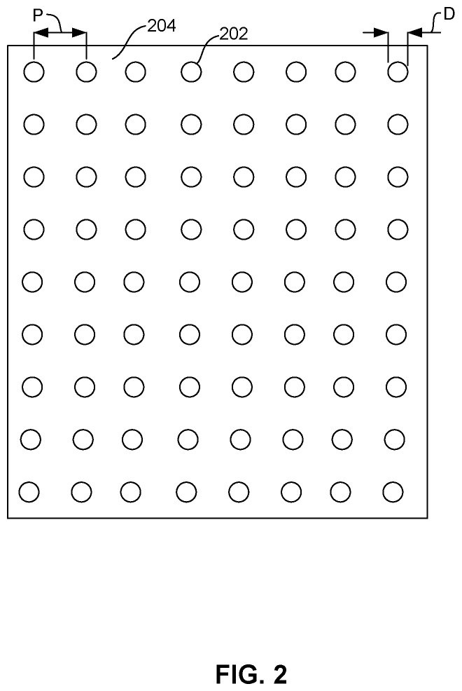

FIG. 2 shows a top down view of an array of memory elements which can be constructed such as the memory element 100 of FIG. 1, but which could also have some other configuration. The memory elements can be formed as pillar structures 202 (shown in top-down cross section in FIG. 2). The pillar structures can be separated from one another by one or more layers of dielectric isolation material 204. The pillar structures can have a diameter D, and can be separated by a center-to-center distance that can be referred to as a pitch P. In a magnetic memory array, in order to increase data density, it is necessary to minimize the pitch P. However, in order to prevent magnetic and electromagnetic interference between memory elements 202, it is also necessary to maintain a certain minimum spacing between memory elements.

However, manufacturing very high-density features on a wafer presents significant physical challenges. Not the least of these challenges relates to the formation of an effective, reliable, high quality photoresist mask for patterning such structures. Generally, such structures can be formed on a wafer by depositing a photoresist, exposing and developing the photoresist to form a mask and then transferring the image of the photoresist mask onto an underlying hard mask layer. The patterned hard mask layer can then be used to define an array of structures in an underlying device material to be patterned. However, in practice, as the array of features becomes denser and the features smaller, the photoresist must be formed as very narrow mask feature elements. In order for the photoresist mask to withstand the process of transferring the image of the photomask onto the underlying hard mask, the photoresist mask must be formed very tall as well as being narrow, thereby having a very high aspect ratio (height/width), as high as >2.5/1. At such a high aspect ratios and densities, the patterned photoresist mask is prone to deformation and toppling of mask features. This of course leads to a significant number of defective patterned features in the array of pillars. In addition, surface tension from the developer solution tends to pull the mask features together, further contributing to deformation and toppling of the mask features.

A process as described below overcomes this challenge by providing a process for forming high quality, small, high density photoresist mask features that can withstand image transfer processes with little or no such deformation or toppling. This advantageously allows for the formation of very high quality, small, high density device features, such as for use in a magnetic memory array. Although the process is described herein for use in forming an array of magnetic memory elements, this is by way of illustrating a practical application of such a process. The process could also be used to form any number of other such small, high density features on a wafer or mask. For example, the below described process could be particularly useful in the formation of a nano-imprinting mask, magnetic logic, or magnetic neuromorphic computing devices.

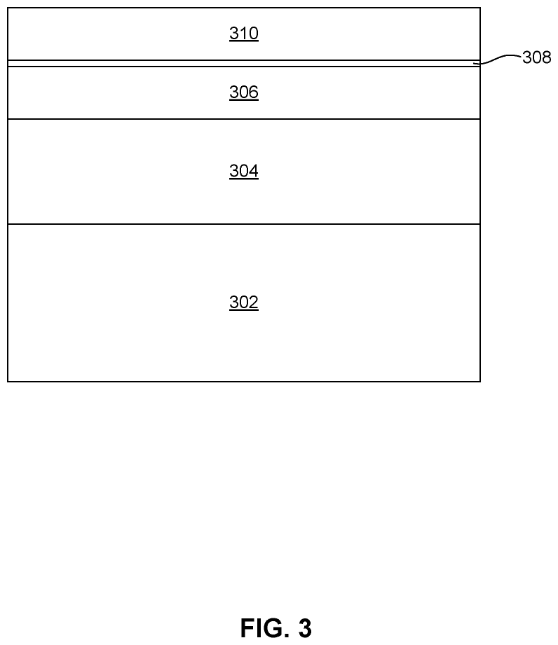

With reference to FIG. 3, a device material layer 304 is deposited over a substrate 302. In a possible embodiment, the device material layer 304 could be a series of layers for forming an array of magnetic memory elements such as the memory element 100 described above with reference to FIG. 1 or having some other structure, and the substrate 302 could be a semiconductor substrate such as silicon which could include CMOS circuitry and a lead layer (not shown). As mentioned, the process could also be used to form other types of arrays of features, such as a nano-imprinting mask. In that case, the substrate 302 and the device material 304 could be a single layer of a hard mask material on a substrate such as quartz. Also, as mentioned above, the process could be used to form other feature arrays as well, such as magnetic logic, or magnetic neuromorphic computing devices.

A hard mask layer 306 is deposited over the device material layer 304. In one embodiment, the hard mask layer 306 could be a layer of TaN or Cr. Then, a thin layer of SiO₂ 308 is deposited over the hard mask layer, and a layer of photoresist 310 is deposited over the SiO₂ layer 308. The SiO₂ layer 308 can be deposited by physical vapor deposition, atomic layer deposition, or sputter deposition. The SiO₂ layer 308 is preferably deposited to be very thin, preferably no thicker than 1 nm (e.g. less than or equal to 1 nm). The SiO₂ layer 308 serves as an adhesion layer for the yet to be formed photoresist mask, as will be described in greater detail herein below. The SiO₂ adhesion layer 308 is preferably deposited as thin as possible, so as to not add to the amount of etching required to transfer the pattern of the yet to be formed photoresist mask onto the underlying hard mask layer 306.

After the SiO₂ adhesion layer 308 has been deposited, the wafer is baked to remove any residual water. The underlying hard mask 306, such as TaN, is highly hydroscopic so baking the wafer is useful for removing any residual water from the hard mask 306 and adhesion layer 308. After baking, the wafer is cooled back to room temperature and then, the surface of the wafer (e.g. the SiO₂ adhesion layer 308) can be treated with hexamethyldisilazane (HMDS).

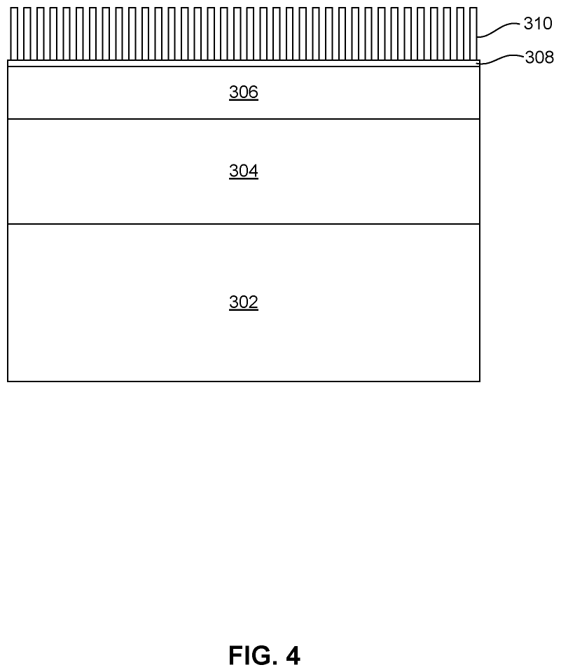

The wafer can then be placed onto a spin chuck and a photoresist material, preferably hydrogen silsequioxane (HSQ) 310 can be applied to the wafer over the adhesion layer 308. The wafer is spun to achieve a desired resist thickness, preferably 80-85 nm. After the resist layer 310 has been applied (e.g. “spun on”), the wafer is again baked and chilled to room temperature. The resist layer 310 is then photolithographically exposed and developed to form a desired photoresist pattern as shown in cross-section in FIG. 4. The exposure of the photoresist layer 310 can be an electron beam patterning exposure. The photoresist 310 can be developed, for example, in an aqueous solution of tetramethyl ammonium hydroxide aqueous or sodium chloride-sodium hydroxide aqueous solution. After development, the wafer is rinsed in deionized (DI) water, preferably gently flowing. After the photoresist layer 310 has been exposed and developed to form the desired mask structure, it is hard baked.

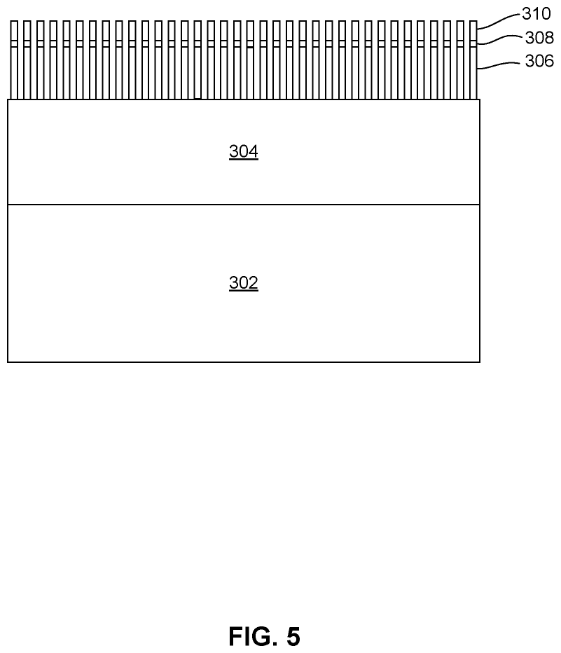

With reference now to FIG. 5, the patterned hard-baked photoresist mask 310 is transferred to the underlying hard mask layer 306 by performing an anisotropic material removal process such as reactive ion etching to remove portions of the adhesion layer 308 and hard mask layer 306 that are not protected by the photoresist mask 310. The reactive ion etching is preferably performed using a chemistry that is chosen to selectively remove the material of the hard mask layer 306. For example, if the hard mask 306 is TaN, then the reactive ion etching process can be performed in a chlorine or fluorine chemistry. A fluorine chemistry could also be used to remove quartz. If the hard mask is Cr, then the reactive ion etching can be performed using a chlorine environment.

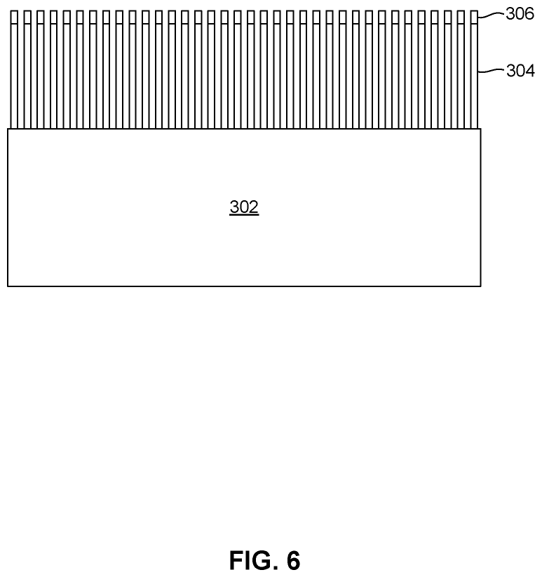

With reference now to FIG. 6, the image of the hard mask 306 is transferred onto the underlying device material layer 304. This can be achieved by performing another reactive ion etching step in a chemistry that is chosen to selectively remove the material or materials of the device layer or an inert ion beam milling step or chemically assisted ion beam etching 304. As mentioned above, the device material layer 304 could be a series of layers of material selected to form an array of magnetic memory elements, in which case many of the layers of the device layer 304 would be magnetic metal alloys. However, the device material layer could also be any number of other materials for which an array of pillar structures is desired. For example, the device material layer 304 could be a material for forming a logic device, a neuromorphic computing device or a nano-printing mask. In the latter case, the device material layer 304 could be, for example, quartz, and the reactive ion etching could be performed using a fluorine chemistry.

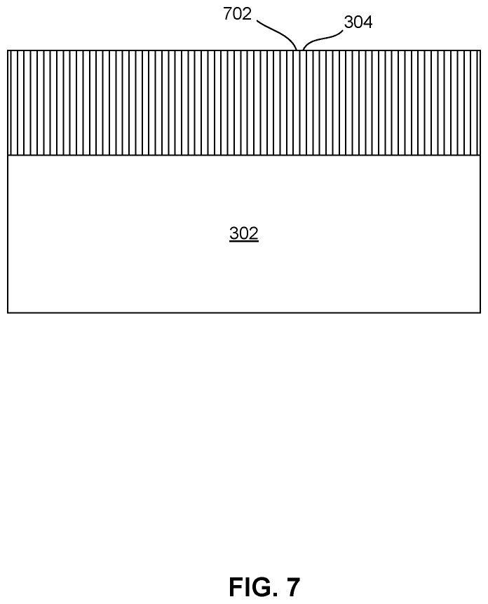

After the desired pattern has been formed on the workpiece material layer 304 as described, a dielectric fill layer 702 can be deposited (depending on the intended structure to be formed) and a chemical mechanical polishing process can be performed, leaving a structure such as that shown in FIG. 7. This step could be useful, for example, when constructing an array of memory elements, but could be omitted if the desired structure is a nano-imprinting mask.

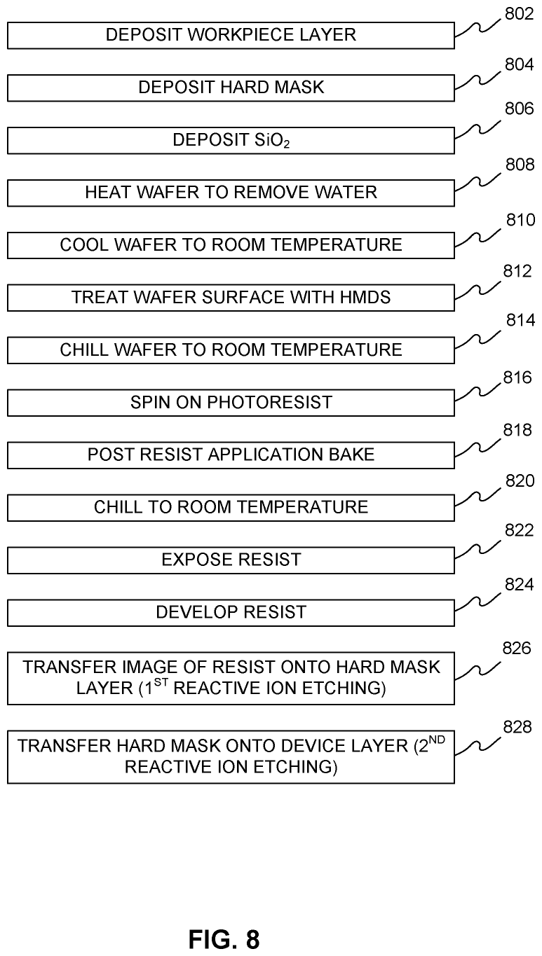

FIG. 8 shows a flowchart summarizing a process for manufacturing small, high density structures. In a step 802 a device material layer is deposited over a substrate. The device material layer could be a series of layers configured to construct an array of magnetic memory elements such as a plurality of magnetic layers and a non-magnetic barrier layer. Alternatively, the device material layer could be some other material such as a layer configured to construct a nano-imprinting mask structure. In that case the device material layer could be a layer of quartz or some other suitable material.

Then, in a step 804, a hard mask layer is deposited. The hard mask layer could be a layer of TaN or Cr. In a step 806, a thin layer of SiO₂ is deposited over the hard mask layer. The layer of SiO₂ can be deposited by, for example, physical vapor deposition, atomic layer deposition or sputter deposition, and is preferably deposited to a thickness of 1 nm or less.

In a step 808 the wafer is heated to remove any residual water, and then in a step 810 the wafer is cooled back to room temperature. Then, in a step 812 the surface is treated with an adhesion promoter such as hexamethyldisilazane (HMDS). Then, in a step 814 the wafer is again chilled to room.

In a step 816, a photoresist material is applied. The photoresist can be hydrogen silsesquioxane (HSQ) and can be applied by a spin-on technique by placing the wafer on a spin chuck and spinning the wafer until a desired photoresist thickness is achieved. Then, in a step 818 a photoresist application bake is performed, and in a step 820, the wafer is again cooled to room temperature.

In a step 822, the photoresist is photolithographically exposed. The exposure can be performed using electron beam exposure or by other photolithographic processes such as using a stepper or scanner tool with a system of lenses. Then, in a step 824 the exposed photoresist is developed. The photoresist can be developed using a material such as tetramethyl ammonium hydroxide aqueous solution or sodium chloride-sodium hydroxide aqueous solution. The wafer is then rinsed for about a minute in gently flowing deionized (DI) water. The resist can be heated to “hard bake” the patterned, developed resist mask. Then, in a step 826, the image of the patterned resist mask is transferred to the hard-mask layer. This can be accomplished by performing a reactive ion etching step using a chemistry that is chosen to selectively remove the hard mask material.

Then, in a step 828, a second etching can be performed to transfer the image of the hard mask onto the underlying device layer. The etching process can be done with reactive ion etching if volatile reaction products are formed or by ion beam etching. This second etch is preferably performed using a chemistry that is chosen to selectively remove the device material. If the process is intended to pattern a magnetic memory array, then the device layer can be a series of layers such as magnetic layers as described above with reference to FIG. 1. If the process is intended for the formation of a nano-imprinting mask, then the device layer can a material such as quartz.

The above process provides a reliable, effective method for manufacturing patterned arrays at very high density. As discussed, the process provides excellent photo mask integrity by preventing the toppling or deformation of high aspect ratio photoresist masks during manufacture. Although the process has been described with reference to the formation of magnetic memory arrays or nano-imprinting masks, the process could also be beneficial in forming any number of other high-density arrays as well.

While various embodiments have been described above, it should be understood that they have been presented by way of example only and not limitation. Other embodiments falling within the scope of the invention may also become apparent to those skilled in the art. Thus, the breadth and scope of the inventions should not be limited by any of the above-described exemplary embodiments but should be defined only in accordance with the following claims and their equivalents.

What is claimed is:

1. A method for forming a high-density array of features, the method comprising:
forming a device material layer on a wafer;
depositing a hard mask layer over the device material layer;
depositing a SiO₂ adhesion layer over the hard mask layer;
forming a photoresist mask over the SiO₂ adhesion layer;
transferring the image of the photoresist mask onto the underlying SiO₂ adhesion layer and hard mask layer; and
transferring the image of the hard mask layer onto the underlying device material.

2. The method as in claim 1, wherein the SiO₂ adhesion layer is deposited to a thickness that is no greater than 2 nm.

3. The method as in claim 1, further comprising, after depositing the SiO₂ adhesion layer, baking the wafer to a temperature of greater than 120 C.

4. The method as in claim 1, further comprising, after depositing the SiO₂ adhesion layer and before forming the photoresist mask, treating the SiO₂ adhesion layer with an adhesion promoter.

5. The method as in claim 1, further comprising, after depositing the SiO₂ adhesion layer and before forming the photoresist mask, treating the SiO₂ adhesion layer with hexamethyldisilazane.

6. The method as in claim 1, wherein the forming a photoresist mask further comprises spinning on a photoresist material, photolithographically exposing the photoresist material, developing the photoresist material and hard baking the developed photoresist material.

7. The method as in claim 6, wherein the developing the photoresist is performed using a tetramethyl ammonium hydroxide aqueous, sodium chloride-sodium hydroxide aqueous solution.

8. The method as in claim 1, wherein the device material comprises a plurality of layers configured to define an array of magnetic memory elements.

9. The method as in claim 1, wherein the device material comprises a material configured to form a nano-imprinting mask.

10. The method as in claim 9, wherein the device material comprises quartz.

11. The method as in claim 1, wherein the hard mask comprises one or more of Cr and TaN.

12. The method as in claim 1, wherein the SiO₂ adhesion layer is deposited by physical vapor deposition, atomic layer deposition or sputter deposition.

13. The method as in claim 1, wherein the image of the photoresist mask is transferred onto the underlying SiO₂ adhesion layer and the hard mask layer by performing a reactive ion etching using a chemistry that is chosen to selectively remove the material of the hard mask layer.

14. The method as in claim 1, wherein the photoresist mask is formed by spinning on a photoresist material and performing an electron beam patterning of the photoresist material.

15. A method for manufacturing a magnetic memory array, the method comprising:
providing a substrate;
depositing a series of memory element layers over the substrate;
depositing a hard mask layer over the series of memory element materials;
depositing a SiO₂ adhesion layer over the hard mask layer;
depositing a layer of photoresist over the SiO₂ adhesion layer;
patterning and developing the photoresist to form a photoresist mask;
performing a performing first material process to transfer the image of the image of the photoresist mask onto the underlying SiO₂ adhesion layer and hard-mask; and
performing a second material removal process to transfer the image of the hard-mask onto the underlying series of magnetic memory element layers.

16. The method as in claim 15, wherein the first material removal process comprises reactive ion etching and the second material removal process comprises ion milling.

17. The material removal process as in claim 15, wherein the first material removal process comprises a first reactive ion etching in a first chemistry and the second material removal process comprises a second reactive ion etching using a second chemistry that is different from the first chemistry.

18. The method as in claim 15, wherein the SiO₂ adhesion layer is deposited to a thickness not greater than 1 nm.

19. The method as in claim 15, further comprising after depositing the SiO₂ adhesion layer, performing a baking.

20. The method as in claim 15, wherein the SiO₂ adhesion layer is deposited by physical vapor deposition, atomic layer deposition or sputter deposition.
